(19) United States
(12) Patent Application Publication
(10) Pub. No.: US 2011/0157536 A1
(43) Pub. Date: Jun. 30, 2011

(54) ELECTRIC CIRCUIT STRUCTURE

(75) Inventor: Tadashi Inui, Osaka-shi (JP)

(73) Assignee: SHARP KABUSHIKI KAISHA, Osaka-shi, Osaka (JP)

(21) Appl. No.: 13/056,993

(22) PCT Filed: Jul. 31, 2009
(86) PCT No.: PCT/JP2009/063683

§ 371 Date: Feb. 1, 2011

(30) Foreign Application Priority Data
Aug. 11, 2008 (JP) 2008-207185

(51) Int. Cl. G02F 1/1345; H05K 7/00

(52) U.S. Cl. 349/151; 361/752

(57) ABSTRACT

Provided is an electric circuit structure for solving the problem that a flexible substrate adhered to a back face of a mechanical member is peeled off due to repulsion generated at a folding part of the flexible substrate connected to a circuit board. The structure is provided with; a bottomed and frame-shaped mechanical member (9); a circuit substrate (1) that is to be housed inside the mechanical member (9) and that has an electric circuit element formed on the surface of the substrate; and a flexible substrate (10) that has a connection terminal formed at one end part (10a) and connected to an electrode terminal (7) formed on the circuit board (1) and that is folded at a folding part (10b) on a side face of the mechanical member (9) while being adhered at another end part (10c) opposite to the end part (10a), to the back face of the mechanical member (9). A deformation preventing material (11) is applied to the outer surface of the folding part (10b) of the flexible substrate (10), and the deformation preventing material (11) is cured by ultraviolet rays or heat after the flexible substrate (10) is folded.

### TECHNICAL FIELD

The present invention relates to an electric circuit structure such as a liquid crystal display having a flexible substrate connected at one end part to a circuit board and connected at the other end part to a back face of a mechanical member in which the circuit board is housed. In particular, the present invention relates to an electric circuit structure for preventing peeling of the flexible substrate from the mechanical member.

### BACKGROUND ART

A panel substrate for forming a flat type image display element such as a liquid crystal panel is a circuit board that has an electrode functioning as a pixel and electric circuit elements such as metal wires provided on the inner surface. In particular, for an active matrix substrate used to display images with higher precision and higher responsibility, a switching element such as TFT is formed, and a COG (Chip On Glass) technique or the like for forming a part of drive circuit on the panel is employed.

An electrode terminal for external connection is provided on the panel substrate of the liquid crystal panel, and various signals for displaying images and a power source voltage for the panel substrate to operate as a circuit board are fed from peripheral circuit boards other than the liquid crystal panel by means of a flexible substrate to be connected to the electrode terminal. The liquid crystal panel and the peripheral circuit board, and further a backlight or the like are housed in a bottomed and frame-shaped mechanical member called bezel, thereby forming a liquid crystal display as an electric circuit structure.

The flexible substrate is joined at one end part to the electrode terminal of the panel, and forms a folding part bent on a side face of the bezel so as to reach the back face of the bezel, and adhered at the opposite end part to the back face of the bezel. In such a liquid crystal display, the flexible substrate has resilience caused by its elasticity, and thus repulsion is generated to cancel the bend at the folding part.

Conventionally, for preventing a lift of the liquid crystal panel caused by the repulsion of the flexible substrate, a frame configuration for pressing the liquid crystal panel to the inside of the bezel has been proposed (see Patent document 1).

### PRIOR ART DOCUMENT(S)

### Patent Document(s)

Patent document 1: JP 2006-98811

### DISCLOSURE OF INVENTION

### Problem to be Solved by the Invention

However, problems caused by the repulsion generated at the folding part of the flexible substrate are not limited to those relating to the above-mentioned lift of the liquid crystal panel. There is also a problem that the flexible substrate is peeled off at the part adhered to the back face of the bezel.

The method as described in the Patent document 1 using a frame configuration to press the liquid crystal panel does not include generation of any force to prevent the deformation in the flexible substrate, and thus the effect is limited. Moreover, since the liquid crystal panel is fixed firmly, the method as described in Patent document 1 causes a new problem that a force to peel the flexible substrate off from the back face of the bezel acts more strongly.

Therefore, with the foregoing in mind, it is an object of the present invention to provide an electric circuit structure for solving the problem that the flexible substrate adhered to the back face of the mechanical member is peeled off due to the repulsion generated at the folding part of the flexible substrate connected to the circuit board.

### Means for Solving Problem

For solving the above-mentioned problems, an electric circuit structure of the present invention is characterized in that it includes: a bottomed and frame-shaped mechanical member; a circuit board to be housed in the mechanical member, on which an electric circuit element is formed; and a flexible substrate having a connection terminal formed at one end part, the connection terminal is connected to an electrode terminal formed on the circuit board. The flexible substrate is folded at a folding part on a side face of the mechanical member and adhered at another end part at the opposite side to the back face of the mechanical member. The flexible substrate has a deformation preventing material that is applied on the outer surface at the folding part, and after folding the flexible substrate, the deformation preventing material is cured by ultraviolet rays or heat.

Further, a liquid crystal display of the present invention is the electric circuit structure of the present invention, which is characterized in that the circuit board is a panel substrate that forms a liquid crystal panel in combination with an opposite substrate adhered to each other with a predetermined space, sandwiching a liquid crystal layer.

### Effects of the Invention

Since the deformation preventing material suppresses repulsion generated at the folding part of the flexible substrate, the present invention can provide an electric circuit structure that can prevent effectively peeling of the flexible substrate from the back face of the mechanical member, and also a liquid crystal display.

### BRIEF DESCRIPTION OF DRAWINGS

FIG. 1 is a perspective view showing a configuration of a liquid crystal display according to an embodiment of the present invention.

FIG. 2 is a plan view showing a back face of a liquid crystal display according to an embodiment of the present invention.

FIG. 3 show application state of a deformation preventing material at the time of measurement of effect in prevention of deformation of a flexible substrate, by the deformation preventing material. FIG. 3A shows a case where the deformation preventing material is applied longitudinally with respect to the longitudinal direction of the flexible substrate. FIG. 3B shows a case where the deformation preventing material is applied laterally with respect to the longitudinal direction of the flexible substrate.

FIG. 4 shows deformed states of a flexible substrate at the time of measurement of effect in prevention of deformation of a flexible substrate, by the deformation preventing material. FIG. 4A shows a case where the repulsion of the flexible substrate is suppressed substantially. FIG. 4B shows a case where repulsion remains on a flexible substrate.

### DESCRIPTION OF THE INVENTION

An electric circuit structure according to the present invention a bottomed and frame-shaped mechanical member; a circuit board to be housed in the mechanical member, on which an electric circuit element is formed; and a flexible substrate having a connection terminal formed at one end part, the connection terminal is connected to an electrode terminal formed on the circuit board, and the flexible substrate is folded at a folding part on a side face of the mechanical member and adhered at another end part at the opposite side to the back face of the mechanical member. The flexible substrate has a deformation preventing material that is applied on the outer surface at the folding part and that is cured by either ultraviolet rays or heat not lower than room temperature in a state where the flexible substrate is folded.

Due to this configuration, the deformation preventing material formed on the outer surface at the folding part of the flexible substrate suppresses the repulsion generated at the folding part so as to suppress the change in the shape of the flexible substrate. Therefore, the problem of peeling of the flexible substrate from the back face of the mechanical member can be prevented effectively without changing the configuration of the flexible substrate.

In the electric circuit structure configured as described above, it is preferable that the deformation preventing material is an ultraviolet-curing resin based on polyurethane methacrylate resin, or the deformation preventing material is an epoxy thermosetting resin.

These materials can be applied easily on the flexible substrate, and cured due to ultraviolet irradiation or absorption of heat not lower than room temperature, thereby preventing effectively deformation of the flexible substrate.

It is also preferable in the configuration that the deformation preventing material is applied on a tape-shaped member, and the tape-shaped member is stuck on the flexible substrate. Thereby, it is possible to form a deformation preventing material of a predetermined shape on a predetermined site of the flexible substrate.

It is also preferable in the configuration that the electric circuit structure is a liquid crystal display, and the circuit board is a panel substrate that forms a liquid crystal panel in combination with an opposite substrate adhered to each other with a predetermined space, sandwiching a liquid crystal layer. Thereby, it is possible to prevent deformation of the flexible substrate at the folding part and thus to obtain a liquid crystal display that prevents peeling of the flexible substrate from the back face of the mechanical member.

Hereinafter, an embodiment of the present invention will be described with reference to the attached drawings.

In the following description of embodiment of the present invention, the electric circuit structure according to the present invention is provided as a liquid crystal display to be used as a display for a mobile phone or a mobile apparatus. It should be noted however, that the description below does not limit the intended use of the electric circuit structure according to the present invention. The electric circuit structure of the present invention is not limited to such a liquid crystal display, but can be applied to various kinds of flat type display devices such as organic/inorganic EL displays and field emission type cold cathode displays. Further, the electric circuit structure of the present invention can be applied to not only display devices but any kinds of modules like drive circuits for acoustic systems and information processors, where a flexible substrate connected at one end part to a circuit board is folded at a folding part and adhered to the back face of the mechanical member, and where the circuit board is housed in the structure and integrated. Even if it is used as a liquid crystal display, the intended use is not limited to a display for a mobile phone or a mobile apparatus, but it can be used also for various monitors for personal computers and television sets.

It should be noted that each of the drawings for reference shows only main components necessary for explanation of the present invention in a simple manner, among the components in the embodiments of the present invention. Therefore, the display device according to the present invention can be provided with any arbitrary components not shown in the drawings for reference. And the dimensions of the components in each drawing do not necessarily reflect the precise dimensions of the actual components, the precise proportions in the dimensions or the like among the respective components.

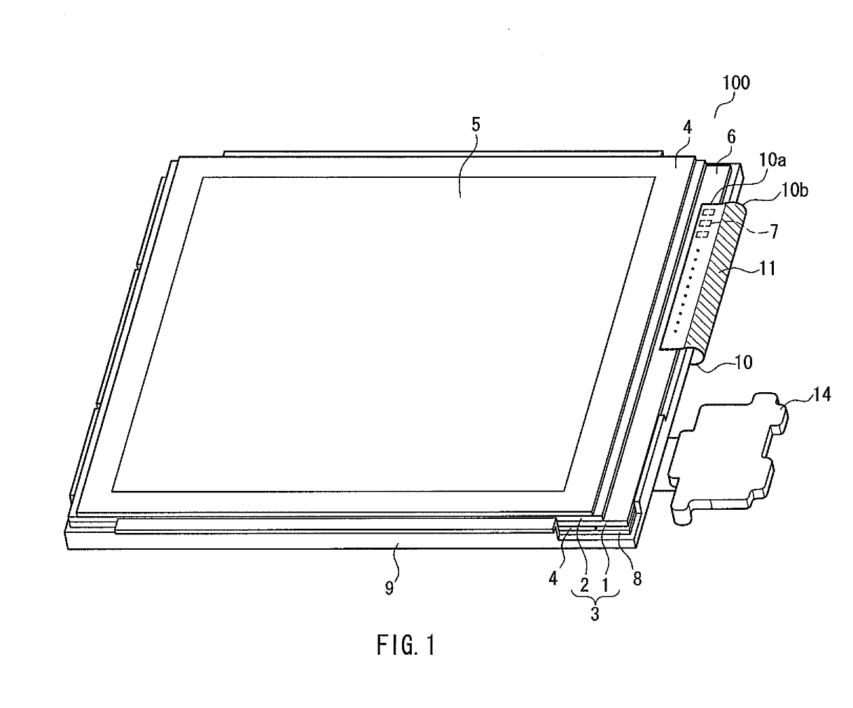

FIG. 1 is a perspective view showing a liquid crystal display according to an embodiment of the present invention.

A liquid crystal display 100 of the present embodiment has a liquid crystal panel 3 formed of a panel substrate 1 as a circuit board and an opposite substrate 2 disposed facing the panel substrate 1 with a predetermined space. A pair of polarizing plates 4 are stuck on the both outer surfaces of the liquid crystal panel 3, namely, on the respective outer surfaces of the panel substrate 1 and the opposite substrate 2.

The panel substrate 1 is an active matrix substrate. On one surface of the panel substrate 1 facing the opposite substrate 2, pixel electrodes (not shown) are arranged in matrix, i.e., arranged in plural lines and plural columns. The pixel electrodes provide a display region 5 for displaying images on the liquid crystal panel 3. A plurality of gate lines arranged in the line direction of the pixel electrodes, a plurality of source lines arranged in the column direction, and TFTs arranged in the vicinity of intersections of the crossing gate lines and source lines and connected to the respective pixel electrodes are formed on the display region 5 of the panel substrate 1. The gate lines, the source lines and the TFTs are not shown in the drawing.

Similarly, a sealant for adhering the panel substrate 1 and the opposite substrate 2, and a liquid crystal layer sandwiched between the panel substrate 1 and the opposite substrate 2 are not shown in the drawing.

The panel substrate 1 has a slightly larger surface area than the opposite substrate 2, and its exposed surface forms a mounting region 6. On the mounting region 6, an electrode terminal 7 is formed to apply predetermined voltages and signals to the various wirings such as the gate lines and the source lines and also to the various electric circuit elements such as TFT formed on the panel substrate 1. In a case where the COG (Chip On Glass) technique is employed, a drive semiconductor element or the like for driving the liquid crystal panel 3 will be packaged on this mounting region 6.

On the back face of the liquid crystal panel 3, a backlight 8 for emitting light necessary for displaying images on the liquid crystal panel 3 is disposed. Though the details are not illustrated in FIG. 1, the backlight 8 of the liquid crystal display 100 according to the present embodiment is either a sidelight type or an edge-light type for example, which is formed of a flat light guide and a light source such as a cold cathode ray tube or a light-emitting diode provided on the side face. Light emitted from the light source and entering from the side face of the light guide is reflected repeatedly inside the light guide so as to be diffused and transmitted, and then irradiated as uniform light from the main surface of the light guide at the side facing the liquid crystal panel 3.

The backlight 8 of the liquid crystal display 100 of the present embodiment is not limited to the above-mentioned sidelight type, but a so-called direct type also can be used. A direct type backlight has a light source disposed plainly on the back face of the liquid crystal panel 3 so as to emit light toward the liquid crystal panel 3, thereby the light from the light source is irradiated on the liquid crystal panel via an optical sheet such as a condensing sheet or a diffusion sheet. Similarly, the light source is not limited to the cold cathode ray tube or the light-emitting diode, but various kinds of light sources such as hot cathode ray tube, an EL emitter or the like can be used.

Similarly, the liquid crystal panel 3 is not limited to a transmission type or semi-transmission type that uses irradiation from the backlight 8 for displaying images. A reflection type liquid crystal panel 3 that reflects external light entering through the opposite substrate 2 of the liquid crystal panel 3 with a reflection electrode formed on the panel substrate 1 can be applied as well. In this case, the backlight 8 can be eliminated.

Both the liquid crystal panel 3 and the backlight 8 are housed in a bezel 9 as a bottomed and frame-shaped mechanical member. The bezel 9, which is required to be light-weight and to have a certain strength, is made of a metal such as aluminum or a resin such as a synthetic resin.

It should be noted that a protrusion (not shown) or the like for holding the liquid crystal panel 3 and the backlight 8 housed inside the bezel 9 may be formed on the inner wall of the bezel 9. Further, a protrusion or a recess for adhering the bezel 9 to a frame of an image display unit of an apparatus such as a mobile phone or a mobile apparatus may be formed on the liquid crystal panel 3 at the image display surface side, namely, at the upper end in FIG. 1. Furthermore, on the sidewall or the bottom of the bezel 9, apertures may be formed to discharge heat generated at the backlight 8 or the various circuit parts housed within or to decrease the weight of the bezel 9.

To the electrode terminal 7 formed in the mounting region 6 of the panel substrate 1, a flexible substrate 10 for applying a signal and a voltage for activating the liquid crystal panel 3 is connected. The flexible substrate 10 is also called FPC (Flexible Printed Circuit), and it has a three-layered structure provided by sandwiching a fine wire of a copper foil or the like with flexible resin films. And at one end part 10a of the flexible substrate 10, a connection part (not shown) with its inner copper foil exposed is formed at a position corresponding to the arrangement of the electrode terminal 7 formed on the mounting region 6 of the panel substrate 1, and the electrode terminal 7 and the connection part are positioned and adhered to each other so as to provide electric conductivity. For the purpose of physically adhering the electric terminal 7 of the panel substrate 1 and the connection part of the flexible substrate 10 and simultaneously obtaining electric conductivity, a film material called an anisotropic conductive film (ACF) containing electroconductive particles is used.

The flexible substrate 10 with a folding part that is bent on a side face of the bezel 9 is disposed to reach the backside of the bezel 9, and an end part thereof, which is opposite to the end part adhered to the panel substrate 1, is adhered to the back face of the bezel 9.

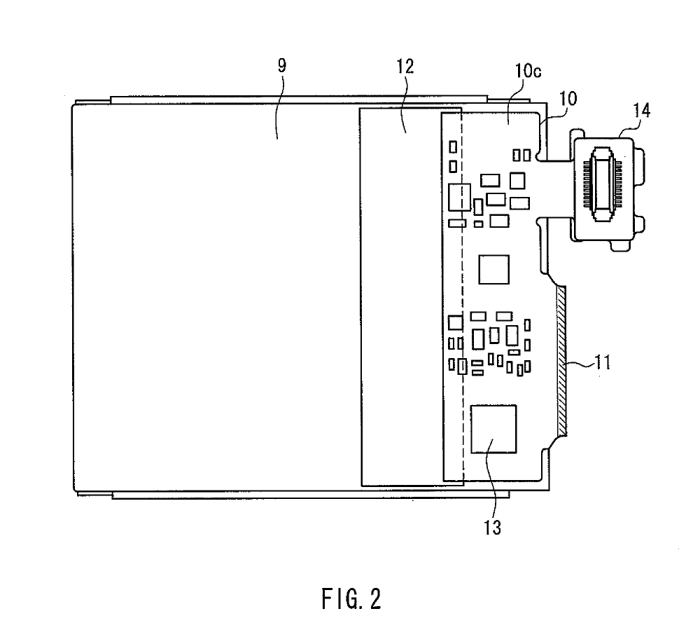

Hereinafter, this structure will be described with reference to FIG. 2 as a plan view showing the liquid crystal display 100 of the present embodiment from the backside, namely, from behind the image display surface.

As shown in FIG. 2, on the image display surface side of the liquid crystal display 100, the flexible substrate 10 connected at one end part 10a thereof to the panel substrate 1 is folded at a folding part 10b positioned on the side face of the bezel 9 toward the backside of the bezel 9. The other end part 10c of the flexible substrate 10, which is positioned opposite to the end part 10a is shaped to cover a part of the bezel 9, and thus the flexible substrate 10 is adhered at this end part 10c to the back face of the bezel 9.

On the back face of the bezel 9, a signal circuit for processing image signals to be displayed on the liquid crystal panel 3 and/or a back face circuit board 12 packaging a drive circuit or the like of the backlight 8 integrated in the bezel 9 are disposed. The end part 10c of the flexible substrate 10 is connected to this back face circuit board 12.

At the end part 10c of the flexible substrate 10, circuit elements 13 such as a semiconductor chip and a capacitor are disposed. In the example as shown in FIG. 2, these circuit elements 13 are packaged directly on the end part 10c of the flexible substrate 10 by employing the TCP (Tape Carrier Package) technique. Alternatively, it is possible to package the circuit elements 13 on a hard resin substrate such as polycarbonate, and to adhere this hard resin substrate to the flexible substrate 10.

On the outer surface of the folding part 10b of the flexible substrate 10, a deformation preventing material 11 is applied. This deformation preventing material will be detailed later.

The liquid crystal display 100 is formed to be a module as a unit of electric circuit structure that has capability of displaying images by only inputting predetermined voltage and signal from the exterior, and it has a control unit 14 in which a semiconductor integrated circuit for controlling the entire liquid crystal display 100 is to be formed. In the liquid crystal display 100 of the present embodiment, the control unit 14 is formed as an extension from the end part 10c of the flexible substrate 10.

The deformation preventing material 11 provided on the folding part 10b of the flexible substrate 10 is cured by ultraviolet rays or heat not lower than room temperature, in a state where the flexible substrate 10 has been folded.

The deformation preventing material 11 may be selected suitably from the viewpoint of easiness in application, compatibility with the material of the flexible substrate 10, curability under a condition without affecting the components like the flexible substrate and the liquid crystal panel, toughness and flexibility after curing, and the like. Here, favorable strength of the cured deformation preventing material 11 is considered as a hardness of about 70 (Share D: ASTM D7720).

For example, in a case of using an ultraviolet-curable material, a material based on polyurethane methacrylate resin is preferred since it cured rapidly by ultraviolet rays and it has both toughness and flexibility. Specifically, for example, “LOCTITE 3523UV” (product name) manufactured by Henkel Japan Ltd. can be used. Since such an anaerobic adhesive based on polyurethane methacrylate resin can be cured by only irradiation of ultraviolet rays under a room temperature condition, the flexible substrate 10 and the electric circuit elements disposed around thereof can be prevented from being affected adversely by the environmental condition for curing the deformation preventing material 11. The polyurethane methacrylate resin is not the sole example, but by selecting a material that has both the toughness and flexibility equal to those of the polyurethane methacrylate resin, a deformation preventing material 11 exhibiting excellent resistance against oscillation and impact can be provided.

In a case of using a thermosetting material, for example, a two-pack type epoxy resin adhesive is preferred due to the sufficient strength. Specifically for example, “E-40FL” (product name) manufactured by Henkel Japan Ltd. can be used.

The measures and conditions in applying the deformation preventing material 11 to the flexible substrate 10 are not limited particularly except for a case where there is a time limit from the application up to curing of the above-mentioned material of a room temperature curing type, for example. Therefore alternatively, it is possible to apply the material on the flexible substrate 10 after bending the folding part 10b to have a predetermined shape. Or the material can be applied after the flexible substrate 10 is folded at the folding part 10b in a state where the end part 10a of the flexible substrate 10 is adhered to the mounting region 6 of the panel substrate 1. Furthermore, it is also possible to apply the deformation preventing material 11 after adhering the end part 10a of the flexible substrate 10 to the mounting region 6 of the panel substrate 1 and adhering the end part 10c at the back face of the bezel 9, respectively.

It is effective that the deformation preventing material 11 is applied precisely on the outer surface of the folding part 10b of the flexible substrate 10. In light of this, it is further preferable that the flexible substrate 10 is adhered at the end part 10a to the panel substrate 1 and then folded to have a predetermined shape, for example, by temporally tacking at least at the folding part 10b, for carrying out the application.

For applying the deformation preventing material 11 on the flexible substrate 10, any general methods to apply a solution or a gel on a predetermined area can be used, and the examples include brushing, spray coating, transcription, printing and the like. Among these methods, brushing is preferred most as a method to apply the deformation preventing material 11 easily on a predetermined region.

Thought the deformation preventing material 11 can be applied to a part or the entire outer surface of the folding part 10b of the flexible substrate 10, application on the entire outer surface of the folding part 10b is preferred. The application thickness can be selected suitably within a range to enable to suppress repulsion of the flexible substrate 10. For example, in a case of applying an ultraviolet-curing anaerobic resin adhesive by brushing, the application thickness is selected suitably within a range of about 0.2 mm to about 2.0 mm. Although uniform application thickness is preferred, an excessive precision is not required as long as a predetermined minimum thickness is ensured in the application region.

The application of the deformation preventing material on the flexible substrate 10 is not limited to a direct application, but application via any other medium is available. In an alternative method, for example, a tape-shaped member fitted to the shape of the application area on the flexible substrate 10 is prepared, the deformation preventing material 11 is applied thereon, and the tape-shaped member is stuck on the flexible substrate 10. Needless to note, the tape should be selected to prevent peeling during the curing of the deformation preventing material 11 or an actual use of the liquid crystal display. For the base material of the tape-shaped member, for example, a nonwoven fabric tape having a thickness of about 0.1 mm to about 0.2 mm can be used. On the tape-shaped member, the deformation preventing material 11 can be applied by way of the above-mentioned brushing, for example.

Regarding the level for suppressing the repulsion of the flexible substrate 10, there is not always necessity of suppressing to a state with no deformation in the flexible substrate 10, but a suppression force of about 50% or more is considered as sufficient, because the deformation preventing material 11 of the present invention serves to suppress deformation of the flexible substrate 10 adhered at the both end parts.

In the present specification, the 100% suppression force indicates that, when the deformation preventing material 11 is applied in a state where the flexible substrate 10 is bent so that the both end parts become parallel to each other and then the flexible substrate 10 is relieved from the holding force, the deformation preventing material 11 can keep the deformed state. The 50% suppression force indicates that, when the force to hold the flexible substrate 10 is relieved, the space between the both end parts of the flexible substrate 10 is broadened, and the space becomes twice in comparison with the parallel state. As mentioned above, if about 50% suppression force of the deformation preventing material 11 is sufficient, the amount of application of the deformation preventing material 11 can be reduced.

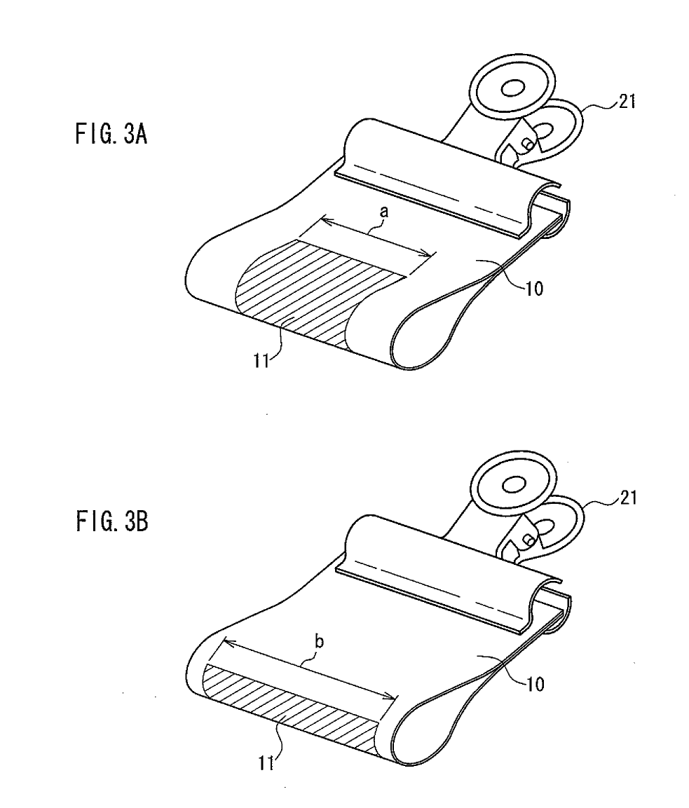

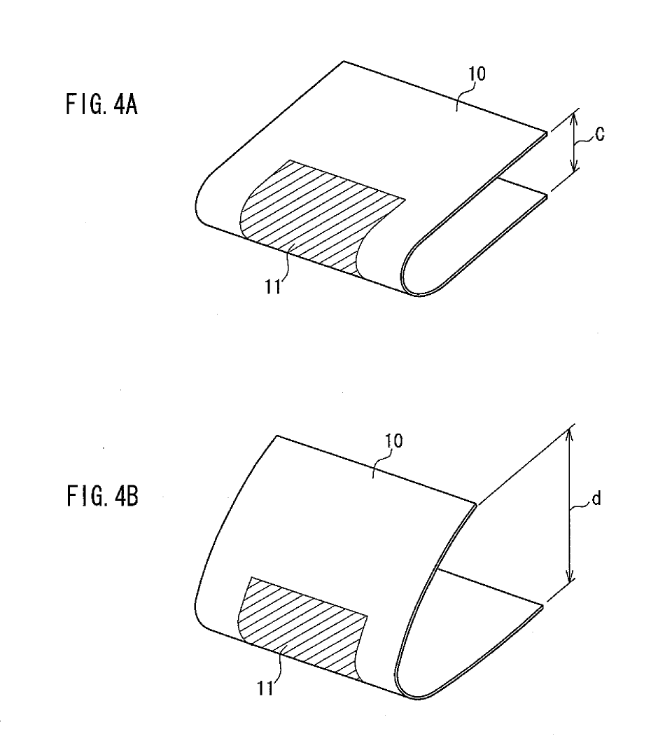

FIGS. 3 and 4 show an experiment for checking the effect of suppressing repulsion of the flexible substrate 10 due to the deformation preventing material 11.

FIGS. 3A and 3B show examples of application states of the deformation preventing material 11 to be measured, and FIGS. 4A and 4B show checking of the repulsion suppression effect by the deformation preventing material 11.

As shown in FIG. 3, for example, a flexible substrate 10 that is 10 mm in width and 40 mm in length is prepared, and the both end parts of the flexible substrate 10 are fixed to each other with a clip 21. Then, the deformation preventing material 11 is applied to the outer surface of the middle and bent part of the flexible substrate 10. Here, two types of application regions are formed, namely, longitudinal application and lateral application with respect to the longitudinal direction of the flexible substrate 10.

In a case of longitudinal application with respect to the longitudinal direction of the flexible substrate 10 as shown in FIG. 3A, the application width as indicated as ‘a’ in FIG. 3A is 3 mm, and the application length is 5 mm. In a case of lateral application with respect to the longitudinal direction of the flexible substrate 10 as shown in FIG. 3B, the application width as indicated as ‘b’ in FIG. 3B is 5 mm, and the application length is 3 mm. The application thickness is uniform and 2 mm for example.

The preferable conditions for curing the deformation preventing material 11 are set suitably in view of the materials of the deformation preventing material 11 in use. For example, in a case of an ultraviolet-curing material, the wavelength and the intensity of the ultraviolet rays to be irradiated, and the irradiation time are set. Specifically, for example, a light beam having a wavelength of 365 nm is irradiated at an intensity of 100 mW/cm² for 15 seconds. In a case of a thermosetting material, the curing temperature and the curing time are set. For example, curing is conducted at temperature of 80° C. for 30 minutes.

For a method of evaluating the effect of these experiments, for example, after curing the deformation preventing material 11, the clip 21 that has been used to fix the flexible substrate 10 is taken out, and the space between the both end parts of the flexible substrate 10 is measured. Specifically, the diagnostic criterion is the space ‘c’ shown in FIG. 4A, which indicates a space between the both end parts of the flexible substrate 10 in a state where the repulsion of the flexible substrate 10 is suppressed and the both end parts become substantially parallel to each other. Referring to this criterion, the actual space ‘d’ between the both end parts of the flexible substrate 10 is measured for every measurement sample. For example, when the space ‘c’ between the substantially parallel end parts of the flexible substrate 10 is 5 mm, the space ‘d’ between the both end parts of the flexible substrate 10 using the deformation preventing material 11 of the measurement sample is 5 mm, the repulsion suppression force will be evaluated as 100%. If the space ‘d’ is 10 mm, then the repulsion suppression force will be evaluated as 50%.

As mentioned above, in the liquid crystal display 100 of the present embodiment, the deformation preventing material 11 is applied on the outer surface of the folding part 10b of the flexible substrate 10, and the deformation preventing material 11 is cured in a state where the flexible substrate 10 is folded. Thereby, the repulsion at the folding part 10b of the flexible substrate 10 can be suppressed efficiently. As a result, the other end part 10c of the flexible substrate 10, which has been adhered to the back face of the bezel 9, can be prevented from peeling off.

In description of the liquid crystal display of the present embodiment, the folding part 10b of the flexible substrate 10 is illustrated in the drawings as being shaped like an arc. However, the present invention is not limited to this example. In an alternative example, the flexible substrate 10 is folded at substantially right angles at two positions of the upper end and the lower end of the side face of the bezel 9, and the space between these two folds is made to be substantially flat. In this case, the deformation preventing material 11 may be applied to the entire folding part including the two folds and the flat part along the side face of the bezel 9, or it may be applied only to the two folds. In any cases, the deformation preventing material 11 serves to suppress the repulsion at the folding part of the flexible substrate 10 and thus to solve effectively the problem of peeling of the flexible substrate 10 from the back face of the bezel 9.

### INDUSTRIAL APPLICABILITY

The present invention, concerning an electric circuit structure where a flexible substrate connected to a circuit board is folded at a folding part and adhered to the back face of a mechanical member, is industrially available for various intended uses including liquid crystal displays.

1. An electric circuit structure comprising:
a bottomed and frame-shaped mechanical member;
a circuit board to be housed in the mechanical member, on which an electric circuit element is formed; and
a flexible substrate having a connection terminal formed at one end part, the connection terminal is connected to an electrode terminal formed on the circuit board, and the flexible substrate is folded at a folding part on a side face of the mechanical member and adhered at another end part at the opposite side to the back face of the mechanical member,
the flexible substrate has a deformation preventing material that is applied on the outer surface at the folding part and that is cured by either ultraviolet rays or heat not lower than room temperature in a state where the flexible substrate is folded.

2. The electric circuit structure according to claim 1, wherein the deformation preventing material is an ultraviolet-curing resin based on polyurethane methacrylate resin.

3. The electric circuit structure according to claim 1, wherein the deformation preventing material is an epoxy thermosetting resin.

4. The electric circuit structure according to claim 1, wherein the deformation preventing material is applied on a tape-shaped member, and the tape-shaped member is stuck to the flexible substrate.

5. The electric circuit structure according to claim 1, wherein the electric circuit structure is a liquid crystal display, and
the circuit board is a panel substrate that forms a liquid crystal panel in combination with an opposite substrate adhered to each other with a predetermined space, sandwiching a liquid crystal layer.
